(19) United States
(12) Patent Application Publication
(10) Pub. No.: US 2026/0072083 A1
(43) Pub. Date: Mar. 12, 2026

(54) HAIRPIN INSPECTION APPARATUS

(71) Applicants: HYUNDAI MOTOR COMPANY, Seoul (KR); Kia Corporation, Seoul (KR); Pyeong Hwa Technology Co., Ltd., Changwon-si (KR); HYUNDAI MOBIS CO., LTD., Seoul (KR)

(72) Inventors: Seungwon SONG, Hwaseong-si (KR); CHANUI PARK, Hwaseong-si (KR); KYOUNG MIN PARK, Hwaseong-si (KR); WON IL KIM, Hwaseong-si (KR); KYUNG SEOK YOO, Changwon-si (KR); TAEK SOO YANG, Changwon-si (KR); YONG SEOK LIM, Changwon-si (KR); Min Soo KANG, Seoul (KR)

(21) Appl. No.: 18/978,850

(22) Filed: Dec. 12, 2024

(30) Foreign Application Priority Data
Sep. 11, 2024 (KR) 10-2024-0123958

(51) Int. Cl. G01R 31/34

(52) U.S. Cl. CPC G01R 31/34

(57) ABSTRACT

A hairpin inspection apparatus includes a base plate, a scan module configured to perform an electrical connection test on an object based on the object passing through a scan area, the scan module including a scanner disposed above the base plate. The apparatus also includes a grasping/feeding module including a grasping unit configured to hold the object. The grasping/feeding module is configured to move the grasping unit along a predetermined closed loop so that the grasped object passes through the scan A controller is configured to determine whether the object passing through the scan area is defective. If the object is determined to be defective, a sorting/collection box receives it from the grasping unit. If the object is determined to be acceptable, a take-out module receives the object from the grasping unit.

### CROSS-REFERENCE TO RELATED APPLICATIONS

This application is based on and claims priority under 35 U.S.C. 119 to Korean Patent Application No. 10-2024-0123958, filed on Sep. 11, 2024, in the Korean Intellectual Property Office, the disclosure of which is herein incorporated by reference in its entirety.

### TECHNICAL FIELD

The present disclosure relates to a hairpin inspection apparatus, and more specifically to an apparatus designed to sort hairpins, which have been bent, into acceptable and defective products by inspecting the shaped portion of each hairpin. This allows for the rapid detection of any damage to the insulating film of the hairpin.

### BACKGROUND

An electric vehicle may be driven through a motor that generates kinetic energy by consuming electrical energy. For example, the motor may include a stator and a rotor. In some cases, a highly conductive copper wire is wound around the stator. When current flows through the wound copper wire, a magnetic field is generated around the stator. The rotor may include a steel core, a magnet, or both. The rotor may rotate due to the influence of the magnetic field generated by the stator.

In some cases, as the density of the copper wire wound around the stator increases, the efficiency and performance of the motor may improve. Accordingly, a copper wire having a quadrangular cross-section may be used in order to more tightly wind the copper wire around the stator.

In some cases, a hairpin-type stator may be used, where multiple hairpins are mounted in the stator slots. For instance, each hairpin may be formed by shaping a copper conducting wire cut to have a predetermined length such that the copper conducting wire has a predetermined shape.

In some cases, the hairpin may be made of a linear copper coil having a rectangular cross-section. The copper coil used for manufacture of the hairpin may be coated with a thin insulating film at an outer surface thereof. The insulating film may be made of an insulating material such as enamel or the like.

In some cases, the linear copper conducting wire is shaped through bending in a procedure of manufacturing the hairpin. The thin insulating film on the surface of the copper conducting wire may be susceptible to damage in a procedure of bending the copper conducting wire. When the insulating film of the hairpin is damaged, the hairpin causes degradation of performance and efficiency of the motor. In some cases, the hairpin with the damaged insulating film may be separately sorted into a defective product.

In some cases, manpower may be used to achieve sorting of defective products, which may increase the process period and cost for sorting acceptable products and defective products.

### SUMMARY

The present disclosure describes an inspection apparatus configured to reduce a process time for finding and sorting a hairpin which has an insulating film damaged in a manufacturing procedure.

The present disclosure describes an inspection apparatus configured to replace or supplement a separate additional inspection of a hairpin performed before shaping of the hairpin in which the insulating film of the hairpin is susceptible to damage.

According to one aspect of the subject matter described in this application, an inspection apparatus for a hairpin of a motor includes a base plate and a scan module that defines a scan area and that is configured to perform an electrical connection test on an object to be inspected based on the object passing through the scan area, the scan module including a scanner disposed above the base plate. The apparatus further includes a grasping/feeding module including a grasping unit configured to grasp the object, the grasping/feeding module being configured to move the grasping unit along a circular path defining a predetermined closed loop to thereby allow the object to pass through the scan area. The apparatus further includes a controller configured to determine whether the object is defective based on the object passing through the scan area, a collector configured to receive the object from the grasping unit based on the controller determining that the object is defective, and a take-out module configured to receive the object from the grasping unit based on the controller determining that the object is not defective.

Implementations according to this aspect can include one or more of the following features. For example, the scan module can include a main frame that is coupled to an upper surface of the base plate and extends upwards from the base plate, a connecting arm coupled to the scanner and configured to move vertically along the main frame, a scan head that is rotatably connected to a lower end of the scanner and that defines the scan area having an inlet opened downward, and a scan brush located in the scan area of the scan head and configured to detect an electrical connection of the object with the scan brush based on the object passing through the scan brush.

In some examples, the scan module can include a variable shaft that connects the lower end of the scanner to an upper end of the scan head and is configured to rotate the scan head by a predetermined angle with respect to the scanner, where the scan head is configured to rotate about a vertical rotation axis relative to the scanner.

In some examples, the scan module can include a variable shaft that connects the lower end of the scanner to an upper end of the scan head and is configured to rotate the scan head by a predetermined angle relative to the scanner, where the scan head is tilted with respect to a horizontal rotation axis by a preset angle with respect to the scanner.

In some implementations, the grasping/feeding module can include a rotation table having an upper surface that defines a circular horizontal plane at at least a portion thereof, and a driving shaft configured to rotate the rotation table about a vertical axis relative to the base plate, where the grasping unit is disposed at the upper surface of the rotation table and spaced apart from the driving shaft by a predetermined distance.

In some implementations, the grasping unit is one of a plurality of grasping units that are disposed at the upper surface of the rotation table and that are spaced apart from one another by an equal distance, where the plurality of grasping units are arranged along the circular path having the driving shaft as a center thereof. In some examples, a number of the plurality of grasping units is N, and the rotation table is configured to rotate around the driving shaft in intervals of 360° divided by N.

In some implementations, the grasping unit can include a sensor configured to sense at least one of a pin head, a pin shoulder, a pin arm, or an electrical connection end of the hairpin, the hairpin being the object to be inspected, an aligner configured to, based on information sensed through the sensor, align the hairpin a predetermined position such that the pin head of the hairpin is directed upwards and is disposed at a predetermined height, and a grasper configured to grasp the hairpin at the predetermined position and fix the hairpin.

In some examples, the take-out module can include a first rail having an inclined linear rail structure, the first rail having a first end that is directed toward the grasping/feeding module and configured to horizontally and vertically move relative to the base plate, and a second rail connected to a second end of the first rail and configured to guide the object to a predetermined position.

In some implementations, the scan brush can include a plurality of metal fibers that extend across the scan area of the scan head, where the scan brush is configured to detect the electrical connection between the hairpin and at least one of the plurality of metal fibers to thereby detect a damage of an insulating material covering the hairpin.

### BRIEF DESCRIPTION OF THE DRAWINGS

The above and other objects, features and other advantages of the present disclosure will be more clearly understood from the following detailed description taken in conjunction with the accompanying drawings:

FIG. 1 is a view showing an example of a hairpin of a motor.

FIG. 2 is a perspective view showing an example of a material coil wound around a winding bobbin.

FIG. 3 is a flowchart showing an example of a procedure of manufacturing a hairpin of a motor.

FIG. 4 is a diagram showing an example of an overall hairpin manufacturing process for the hairpin of the motor.

FIG. 5 is a view schematically showing an example of a hairpin inspection apparatus.

FIG. 6 is a view showing an example of a pin head and pin shoulders of a hairpin to be inspected through the hairpin inspection apparatus.

FIG. 7 is a plan view showing an example of an operation path of a grasping/feeding module in the hairpin inspection apparatus.

FIG. 8 is a view showing an example state in which a hairpin passes through a scan module in the hairpin inspection apparatus.

FIG. 9 is a block diagram showing an example configuration of a grasping unit in the hairpin inspection apparatus.

### DETAILED DESCRIPTION

Hereinafter, one or more implementations of the present disclosure will be described in detail with reference to the accompanying drawings.

In the present disclosure, a first direction X, a second direction Y, and a third direction Z represent respective dimensions in 3-dimensional coordinates used to express a 3-dimentional shape and directions allocated for respective dimensions. Accordingly, the first direction X, the second direction Y, and the third direction Z may be indicated by arrows orthogonally interesting one another at a point in a space.

The present disclosure describes an inspection apparatus 70 for a hairpin 10 of a motor.

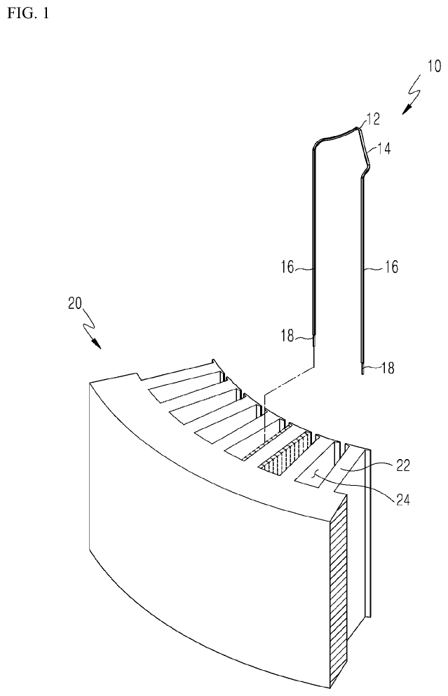

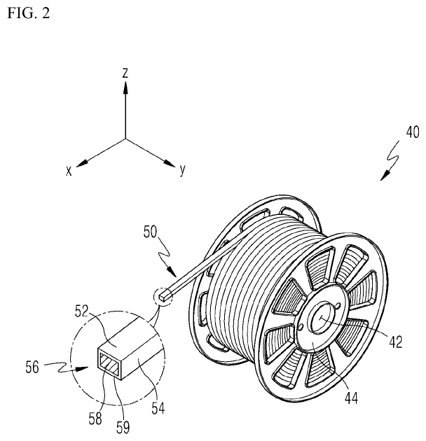

FIG. 1 is a view showing an example of a hairpin of a motor. FIG. 2 is a perspective view showing an example of a material coil wound around a winding bobbin.

In some examples, referring to FIG. 1, the motor (e.g., an electric motor) includes a stator 20 and a rotor. The stator 20 is a fixed part of the motor. The stator 20 has a configuration in which a material coil 50 shown in FIG. 2 is wound around a stator core 22 in a predetermined direction.

As shown in FIG. 1, the material coil 50 is shaped into the form of a hairpin 10 and, as such, the hairpin 10 can be coupled to the stator core 22. The stator core 22 is provided in plural such that a plurality of stator cores 22 is spaced apart from one another by a predetermined distance. Stator slots 24 are formed among the stator cores 22.

Hairpins 10 are mounted in respective stator slots 24. Each hairpin 10 is formed by cutting the material coil 50 to have a predetermined length (referred to as a “feed pitch” hereinafter) and shaping the cut material coil 50.

When current is applied to the hairpins 10 tightly coupled to the stator 20, a magnetic field is formed around the stator 20. Then, the rotor is rotated with respect to the stator 20 as the rotor is influenced by the magnetic field formed around the stator 20.

The hairpin inspection apparatus 70, which is configured in accordance with an implementation of the present disclosure, can be used in a process of manufacturing the hairpins 10 as described above.

Each hairpin 10 is manufactured by shaping the material coil 50 cut to have a predetermined length (feed pitch). Alternatively, in another implementation of the present disclosure, processes of bending and peeling or notching can be previously performed for a predetermined length portion of the material coil 50, and the process of cutting the material coil 50 on a “feed pitch” basis can be performed after the shaping and peeling processes.

The material coil 50 is a linear conducting wire having a rectangular cross-section.

For example, the material coil 50 can include a conducting core 58, which is a conductor, and an insulating film coated on a surface of the conducting core 58. The conducting core 58 is a linear copper member having a quadrangular cross-section, and the insulating film 59 is a coating film formed by coating an insulating material such as enamel or the like on the surface of the conducting core 58 to a predetermined thickness.

The hairpin is formed by cutting the linear material coil 50 to have a predetermined length (feed pitch), and shaping the cut linear material coil 50. Electrical connection ends 18 are formed at opposite ends of the hairpin 10, respectively. Each of the electrical connection ends 18, which are formed at respective ends of the hairpin 10, has a predetermined length.

Each electrical connection end 18 is a portion of the material coil 50 from which the insulating film 59 is removed, and can function as a terminal for electrical connection as the conducting core 58 is outwardly exposed.

The hairpin 10 can be divided into a pin head 12, pin shoulders 14, pin arms 16, and the electrical connection ends 18.

The pin head 12 is disposed at a center of the hairpin 10. The pin head 12 corresponds to a vertex portion formed in accordance with previous bending of the hairpin 10 through a predetermined angle.

The pin head 12 is a point where a pair of pin shoulders 14 meets each other. The pair of pin shoulders 14 is linear portions of the hairpin 10 extending from the pin head 12 in opposite directions, respectively.

The pin shoulders 14 can correspond to two sides of a “virtual triangle” in which the pin head 12 forms a vertex, when viewed in plan view and front view, under the condition that a sharp bent portion of the pin head 12 is directed upwards, as shown in FIG. 1.

The pin arms 16 extend downwards from ends of the pin shoulders 14, respectively. Each pin arm 16 extends linearly in a vertical direction. The electrical connection ends 18 are disposed at lower ends of the pin arms 16, respectively. The two pin arms 16 can be disposed in parallel.

The material coil 50, which is used for manufacture of the hairpin 10, can be a linear member having a rectangular cross-section, and can be stored and transported in a state of being wound around the winding bobbin 40 in most cases.

The winding bobbin 40 can include a cylindrical bobbin core 44, disc-shaped shielding plates respectively mounted to opposite sides of the bobbin core 44, and a central hole 42 which is a through hole formed along a center of the bobbin core 44.

The material coil 50, which has a rectangular cross-section, includes longer side portions 52 and shorter side portions 54.

The pin shoulders 14 are straight portions extending downwards and inclinedly from the pin head 12 toward opposite sides, respectively. The pin arms 16 are straight portions extending downwards from the ends of the pin shoulders 14 after being bent downwards from the ends of the pin shoulders 14, respectively.

The material coil 50, which has been cut on a “feed pitch” basis, that is, the cut material coil 50, is formed with the electrical connection ends 18 at opposite ends thereof, respectively. In addition, a linear wire portion of the cut material coil 50, which interconnects the electrical connection ends 18, is subjected to a bending process such that the linear wire portion has a predetermined 3-dimentional shape. Thus, one hairpin 10, which is divided into the pin head 12, the pin shoulders 14, and the pin arms 16, is manufactured.

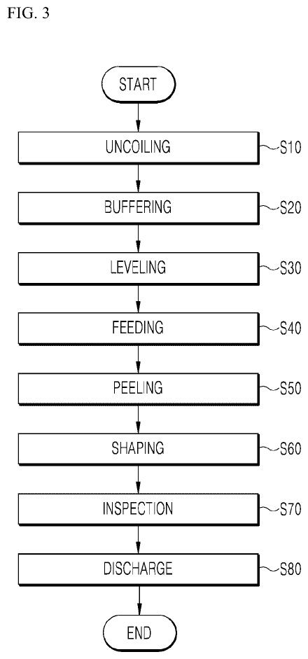

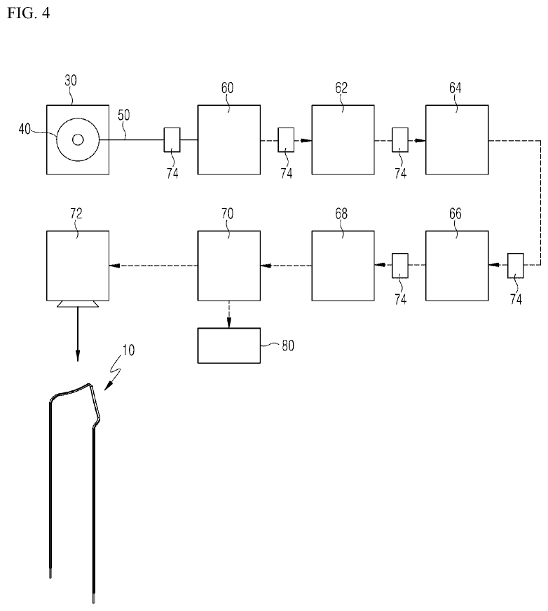

FIG. 3 is a flowchart explaining a procedure of manufacturing a hairpin of a motor. FIG. 4 is a hairpin manufacturing process diagram briefly showing overall processes for manufacturing the hairpin of the motor.

As shown in FIGS. 3 and 4, the process of manufacturing the hairpin 10 can include uncoiling S10, buffering S20, leveling S30, feeding S40, peeling S50, shaping S60, inspection S70, and discharge S80.

In the uncoiling S10, a material coil 50, which has a rectangular cross-section and has been wound around the winding bobbin 40, is unwound by an uncoiling device 30, and is linearly fed in a straight direction, starting from one end thereof.

In the buffering S20, the material coil 50, which is fed while being unwound from the winding bobbin 40, is stored such that the material coil 50 can be subsequently fed by a unit length (feed pitch) for manufacture of one hairpin 10 without delay. That is, the buffering S20 is a procedure for sufficiently securing, by the buffering device 60, a predetermined length (feed pitch) or more of the material coil 50 maintained in a feedable state after being unwound.

The leveling S30 is a procedure for straightly unbending the material coil 50 stored in the winding bobbin 40 in a wound state, using a leveling device 62.

The feeding S40 can be executed through a feeding device 64. The feeding device 64 grasps the material coil 50 and feeds the grasped material coil 50 in a predetermined direction by the predetermined unit length.

The peeling S50 is a procedure for peeling an insulating film 59 made of enamel or the like and coated on a surface of the material coil 50. The peeling S50 can be executed using a peeling device 66. A notching process for electrical connection ends 18, from which the insulating film 59 has been removed, can further be included in the peeling S50.

The shaping S60 is a procedure for cutting the material coil 50 by the “feed pitch” length, which is a length of the material coil 50 for manufacture of one hairpin 10, and then bending the material coil 50 cut by the “feed pitch” length, through a shaping device 68, thereby forming a pin head 12, pin shoulders 14, and pin arms 16.

The inspection S70 is a procedure for inspecting each hairpin 10 fed to an inspection apparatus 70 after being subjected to the shaping S60, and sorting the hairpin 10 into an acceptable product or a defective product.

In the discharge S80, hairpins 10 sorted into acceptable products in the inspection S70 are fed to a discharge device 72. The hairpins 10 sorted into acceptable products are moved along the discharge device 72 to be stacked at predetermined positions, respectively. For instance, the acceptable products are hairpins that have passed the electrical connection test and are determined as not being defective.

Feeding guides 74 can be provided among the devices executing respective processes to guide the material coil 50 in terms of feeding direction and position.

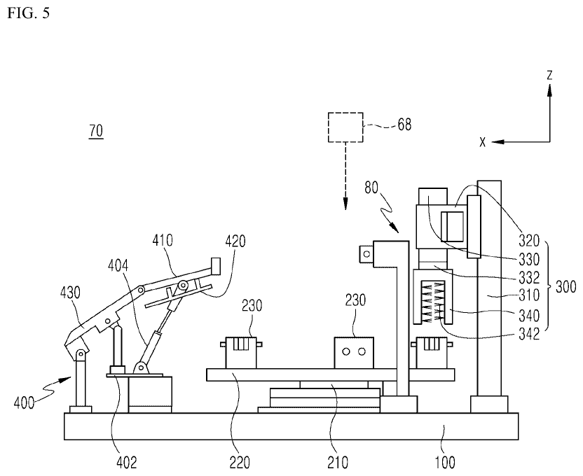

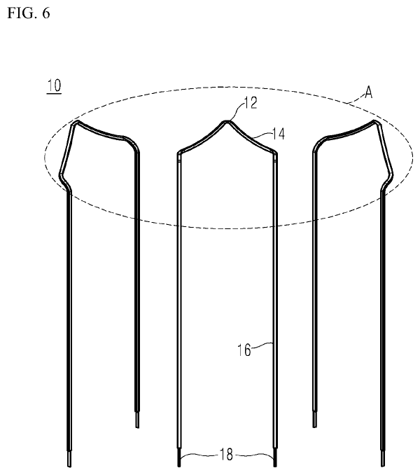

FIG. 5 is a view schematically showing a hairpin inspection apparatus 70 according to an implementation of the present disclosure. FIG. 6 is a view explaining a pin head 12 and pin shoulders 14 of a hairpin 10 to be inspected through the hairpin inspection apparatus 70.

As shown in FIGS. 5 and 6, the hairpin inspection apparatus 70 includes a base plate 100, a scan module 300, a grasping/feeding module 200, a controller 500, a sorted-product collection box 80 (e.g., collector), and a take-out module 400.

The base plate 100 is a base structure on which the inspection apparatus 70 is installed. The base plate 100 takes the form of a flat plate and provides a base enabling the devices to operate stably.

The scan module 300 performs an electrical connection test for an object, to be inspected, passing through a scan area. The scan module 300 includes a main frame 310, a connecting arm 320, a scanner 330, and a scan head 340.

The main frame 310 is fixed on the base plate 100.

The main frame 310 is fixed, at a lower end thereof, to an upper surface of the base plate 100, and can be configured to take the form of a pillar extending upwards straightly.

The main frame 310 supports the connecting arm 320, the scanner 330, and the scan head 340.

The connecting arm 320 is coupled to the main frame 310 to move upwards and downwards in a vertical longitudinal direction of the main frame 310. The connecting arm 320 moves the scanner 330 and the scan head 340 to a predetermined height.

The scanner 330 is coupled to the connecting arm 320, and moves together with the connecting arm 320. The scan head 340 is coupled to a lower end of the scanner 330.

The scanner 330 and the scan head 340 are connected to each other by a variable shaft 332 such that the scan head 340 can rotate through a predetermined angle.

The scan head 340 forms a scan area through which an object to be inspected passes.

The scan head 340 is coupled, at an upper end thereof, to the lower end of the scanner 330, and an inverted-U-shaped groove opened downwards is formed at the scan head 340.

An upper end portion of a hairpin 10, which is an object to be inspected, passes through the inverted-U-shaped groove formed at the scan head 340.

In detail, as shown in FIG. 6, a scan portion A of the hairpin 10, which is shaped through bending, passes through a scan area, that is, the inverted-U-shaped groove formed at the scan head 340.

A scan brush 342 is provided in the scan area of the scan head 340.

The scan brush 342 is disposed in the scan area formed at the scan head 340.

The scan brush 342 determines whether or not electrical connection of the hairpin 10 is secured, by inspecting the scan portion A of the hairpin 10 passing through the scan area.

The scan brush 342 can be made of fine metal fibers and, as such, can collect an electrical signal while being brought into contact with a surface of an object, to be inspected, passing through the scan area. The electrical signal sensed through the scan brush 342 can be used as basic information for determining whether or not an insulating film of the hairpin 10 at the scan portion A has been damaged.

The electrical signal sensed through the scan brush 342 can be transmitted to the controller 500.

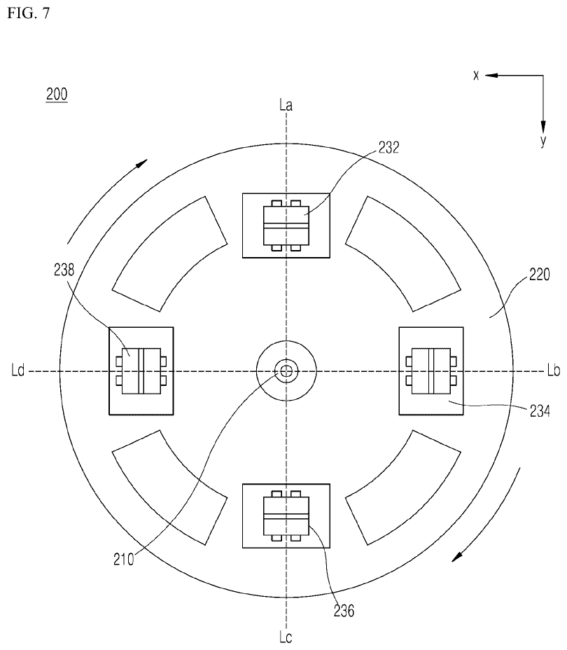

FIG. 7 is a plan view explaining an operation path of the grasping/feeding module 200 in the hairpin inspection apparatus 70.

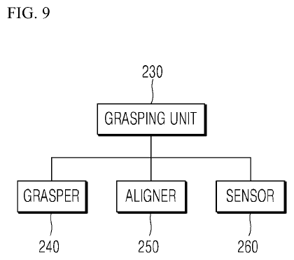

As shown in FIG. 7, the grasping/feeding module 200 includes a driving shaft 210, a rotation table 220, a grasping unit 230, a grasper 240 (FIG. 9), an aligner 250 (FIG. 9), and a sensor 260 (FIG. 9).

The grasping/feeding module 200 grasps an object, to be inspected, received from the shaping device 68, and moves the hairpin 10, which is the object to be inspected, such that the scan portion A of the hairpin 10 passes through the scan area of the scan head 340.

The driving shaft 210 rotates about a rotation axis parallel to a Z-axis on the base plate 100 and, as such, the rotation table 220 connected to the driving shaft 210 is rotated in a clockwise direction on an X-Y plane by a predetermined angle, as shown in FIG. 7.

The rotation table 220 is installed over the base plate 100.

The rotation table 220 has a circular horizontal surface and rotates about a virtual vertical line (a line parallel to the Z-axis) as a central axis thereof. The rotation table 220 is driven by the driving shaft 210 such that the rotation table 220 rotates together with the driving shaft 210.

A plurality of grasping units 230 can be mounted on the rotation table 220. The grasping units 230 are disposed to be spaced apart from the rotation axis of the rotation table 220 by a predetermined distance. In addition, the grasping units 230 are spaced apart from one another by a predetermined distance.

The grasping units 230 are disposed to have a predetermined distance from the driving shaft 210 to which the rotation table 220 is coupled. The grasping units 230 are also disposed to be spaced apart from one another by an angle of 90° on an X-Y plane.

When it is assumed that the plurality of grasping units 230 includes a first grasping unit 232, a second grasping unit 234, a third grasping unit 236, and a fourth grasping unit 238, a point La, at which the first grasping unit 232 is disposed, can be set to a position at which a hairpin 10 is discharged from a previous process (the shaping process) to the inspection apparatus 70.

As described above, an object, to be inspected, discharged from the shaping device 68, can fall downwards from the shaping device 68, and the point at which the object falls downwards from the shaping device 68 can be set to the point La which is the position of the first grasping unit 232 provided at the rotation table 220.

This is only illustrative, and a method or a structure for discharging objects, to be inspected, from the previous process to respective grasping units 230 can be implemented in various manners in accordance with implementations of the present disclosure.

Referring to FIG. 7, the rotation table 220 rotates about the driving shaft 210, and an object to be inspected is supplied to the first grasping unit 232 disposed at the point La. The first grasping unit 232 receives the object at the point La and grasps the object such that the scan portion A of the object is directed upwards.

A method of inspecting an object, to be inspected, through the inspection apparatus 70 can include object receiving, rotational feeding, scanning, defective-product sorting and collection, and acceptable-product take-out.

This will be described in conjunction with the configuration of the rotation table 220. The rotation table 220 includes the plurality of grasping units 230, as described above. As the rotation table 220 rotates, the plurality of grasping units 230 rotates together with the rotation table 220 while maintaining the same radial distance.

For example, the first grasping unit 232 of the rotation table 220 rotates on the X-Y plane, together with the rotation table 220, in accordance with rotation of the rotation table 220. In this case, the first grasping unit 232 totally rotates 360° until the first grasping unit 232 returns to an original position thereof, that is, the point La.

When it is assumed that the number of grasping units 230 provided at the rotation table 220 is N, the rotation table 220 sequentially rotates at intervals of 360°/N, which is an angle obtained by dividing 360° by N, throughout one turn thereof.

That is, the rotation table 220 provided with four grasping units 230 sequentially rotates and stops at intervals of 90° throughout one turn thereof. The rotation table 220 repeats such a rotation/stop procedure at intervals of a predetermined time.

Accordingly, each grasping unit 230 sequentially stays at the point La, a point Lb, a point Lc, and a point Ld for a predetermined time.

As described above, the grasping unit 230 disposed at the point La receives an object, to be inspected, falling downwards from the shaping device 68.

In addition, each grasping unit 230 can discharge a defective product into the sorted-product collection box 80 at the point Lc, and can take out an acceptable product to a predetermined location through the take-out module 400 at the point Ld.

The take-out module 400 includes a vertical-movement rail 410 (first rail) and a take-out rail 430 (second rail).

For example, the vertical-movement rail 410 can be configured to enable an inspected object to slidably move by the gravity and, as such, to move along a predetermined path. That is, the vertical-movement rail 410 can be constituted by an inclined linear rail structure having a predetermined path.

The take-out rail 430 can be a linear rail structure connected to the vertical-movement rail 410. One end of the vertical-movement rail 410, which is a free end, can be disposed over the grasping unit 230 disposed at the point Ld.

The vertical-movement rail 410 is movable such that the free end thereof moves downwards toward the grasping unit 230 disposed at the point Ld and again moves upwards.

An engagement member, which is configured to allow an inspected object to be engaged therewith, can be provided at the free end of the vertical-movement rail 410. The inspected object grasped by the grasping unit 230 can be taken out while slidably moving along the vertical-movement rail 410 and the take-out rail 430 through a procedure in which the free end of the vertical-movement rail 410 moves downwards toward the grasping unit 230 and then moves upwards.

A plurality of guide rails 420, which is configured to assist feeding of the inspected object, can be further provided at opposite sides of the vertical-movement rail 410.

In addition, the vertical-movement rail 410 and/or the take-out rail 430 can be connected to a vertical-movement adjusting shaft 404 configured to enable inclination adjustment and vertical movement of the vertical-movement rail 410 and/or the take-out rail 430.

The vertical-movement adjusting shaft 404 can be rotatably coupled to the vertical-movement rail 410 and/or the take-out rail 430, and can be coupled, at a lower end thereof, to a sliding plate 402 provided on the base plate 100.

The vertical-movement adjusting shaft 404 can be adjusted in length, and the position of the sliding plate 402 on the base plate 100 can be varied.

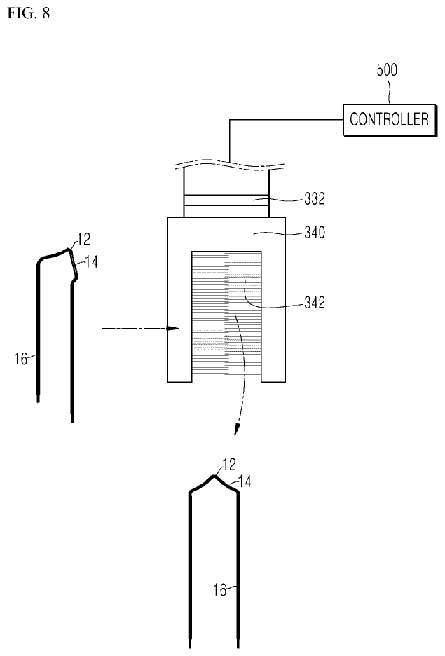

FIG. 8 is a view explaining a state in which the hairpin 10 passes through the scan module 300 in the hairpin inspection apparatus 70.

As shown in FIG. 8, the scan module 300 in the inspection apparatus 70 is disposed on the rotation table 220 between the point Lb and the point Lc.

The scan head 340 is disposed on a path along which the grasping unit 230 stopped at the point Lb rotates toward the point Lc, and the scan portion A of an object, to be inspected, passes through the scan area formed at the scan head 340.

The scan head 340 can be connected to the scanner 330 through the variable shaft 332. The variable shaft 332 can enable the scan head 340 to be tilted or rotated by a predetermined angle with respect to the scanner 330.

When the object to be inspected passes through the scan area, the variable shaft 332 rapidly rotate and tilt the scan head 340, thereby enabling the scan brush 342 to more easily sense an electrical signal from the surface of the object to be inspected.

FIG. 9 is a block diagram showing a configuration of each grasping unit 230 in the hairpin inspection apparatus 70.

As shown in FIG. 9, each grasping unit 230 can include the sensor 260, the aligner 250, and the grasper 240.

The sensor 260 senses a position of at least one of the pin head 12, the pin shoulders 14, the pin arms 16, or the electrical connection ends 18 from the hairpin 10 which is an object to be inspected.

The aligner 250 aligns the pin head 12 of the hairpin 10 to be directed upwards and to be disposed at a predetermined height, based on information sensed through the sensor 260.

The grasper 240 fixes the object, the pin head 12 of which is aligned in terms of direction and height through the aligner 250. The grasper 240 can fix the object, that is, the hairpin 10, by pressing the opposite pin arms 16 of the hairpin 10.

In accordance with the present disclosure, it can be possible to inspect damage of an insulating film of a hairpin based on a portion of the hairpin shaped in a procedure of manufacturing the hairpin. Accordingly, there is an advantage in that it is possible to more rapidly sort a defective product.

In accordance with the present disclosure, inspection of a hairpin can be carried out in succession with a process of shaping the hairpin. Accordingly, there are effects of enhancing inspection efficiency and reducing inspection costs.

In accordance with the present disclosure, there is an advantage in that inspection and sorting of shaped hairpins can be continuously carried out in real time.

Effects attainable in the present disclosure are not limited to the above-described effects, and other effects of the present disclosure not yet described will be more clearly understood by those skilled in the art from the above detailed description.

Heretofore, the implementations of the present disclosure have been described with reference to the accompanying drawings. However, the implementations of the present disclosure are only illustrative, and the present disclosure is not limited to contents of the above-described implementations and the drawings.

It goes without saying that various modifications can be made within the scope of the present disclosure by those skilled in the technical field to which the present disclosure belongs, and the described implementations are a part of the present disclosure.

The scope of the present disclosure is not limited by the described implementations. The scope of the present disclosure should be determined by the technical idea defined in the claims.

In addition, although functions or effects according to configurations are not explicitly described in description of implementations of the present disclosure, it is obvious that functions or effects expectable by the configurations should be acceptable as those of the present disclosure.

What is claimed is:

1. An inspection apparatus for a hairpin of a motor, comprising:
a base plate;
a scan module that defines a scan area and that is configured to perform an electrical connection test on an object to be inspected based on the object passing through the scan area, the scan module comprising a scanner disposed above the base plate;
a grasping/feeding module comprising a grasping unit configured to grasp the object, the grasping/feeding module being configured to move the grasping unit along a circular path defining a predetermined closed loop to thereby allow the object to pass through the scan area;
a controller configured to determine whether the object is defective based on the object passing through the scan area;
a collector configured to receive the object from the grasping unit based on the controller determining that the object is defective; and
a take-out module configured to receive the object from the grasping unit based on the controller determining that the object is not defective.

2. The inspection apparatus according to claim 1, wherein the scan module comprises:
a main frame that is coupled to an upper surface of the base plate and extends upwards from the base plate;
a connecting arm coupled to the scanner and configured to move vertically along the main frame;
a scan head that is rotatably connected to a lower end of the scanner and that defines the scan area having an inlet opened downward; and
a scan brush located in the scan area of the scan head and configured to detect an electrical connection of the object with the scan brush based on the object passing through the scan brush.

3. The inspection apparatus according to claim 2, wherein the scan module further comprises:
a variable shaft that connects the lower end of the scanner to an upper end of the scan head and is configured to rotate the scan head by a predetermined angle with respect to the scanner, and
wherein the scan head is configured to rotate about a vertical rotation axis relative to the scanner.

4. The inspection apparatus according to claim 2, wherein the scan module further comprises:
a variable shaft that connects the lower end of the scanner to an upper end of the scan head and is configured to rotate the scan head by a predetermined angle relative to the scanner, and
wherein the scan head is tilted with respect to a horizontal rotation axis by a preset angle with respect to the scanner.

5. The inspection apparatus according to claim 1, wherein the grasping/feeding module further comprises:
a rotation table having an upper surface that defines a circular horizontal plane at at least a portion thereof; and
a driving shaft configured to rotate the rotation table about a vertical axis relative to the base plate, and
wherein the grasping unit is disposed at the upper surface of the rotation table and spaced apart from the driving shaft by a predetermined distance.

6. The inspection apparatus according to claim 5, wherein the grasping unit is one of a plurality of grasping units that are disposed at the upper surface of the rotation table and that are spaced apart from one another by an equal distance, and
wherein the plurality of grasping units are arranged along the circular path having the driving shaft as a center thereof.

7. The inspection apparatus according to claim 6, wherein a number of the plurality of grasping units is N, and
wherein the rotation table is configured to rotate around the driving shaft in intervals of 360° divided by N.

8. The inspection apparatus according to claim 5, wherein the grasping unit comprises:
a sensor configured to sense at least one of a pin head, a pin shoulder, a pin arm, or an electrical connection end of the hairpin, the hairpin being the object to be inspected;
an aligner configured to, based on information sensed through the sensor, align the hairpin a predetermined position such that the pin head of the hairpin is directed upwards and is disposed at a predetermined height; and
a grasper configured to grasp the hairpin at the predetermined position and fix the hairpin.

9. The inspection apparatus according to claim 1, wherein the take-out module comprises:
a first rail having an inclined linear rail structure, the first rail having a first end that is directed toward the grasping/feeding module and configured to horizontally and vertically move relative to the base plate; and
a second rail connected to a second end of the first rail and configured to guide the object to a predetermined position.

10. The inspection apparatus according to claim 2, wherein the scan brush comprises a plurality of metal fibers that extend across the scan area of the scan head, and
wherein the scan brush is configured to detect the electrical connection between the hairpin and at least one of the plurality of metal fibers to thereby detect a damage of an insulating material covering the hairpin.
